(19) United States
(12) Patent Application Publication
(10) Pub. No.: US 2013/0000689 A1
(43) Pub. Date: Jan. 3, 2013

(54) PHOTOVOLTAIC MODULE SUPPORT ASSEMBLY WITH STANDOFF CLAMPS

(75) Inventor: Rogér Balyon, Santa Clara, CA (US)

(73) Assignee: MiaSolé, Santa Clara, CA (US)

(21) Appl. No.: 13/175,752

(22) Filed: Jul. 1, 2011

(51) Int. Cl. H01L 31/042; H01L 31/18

(52) U.S. Cl. 136/244; 29/428; 29/525.01

(57) ABSTRACT

Apparatus and techniques for mounting frameless photovoltaic modules to eliminate obstruction of corner and edge-mounted module components with longitudinally-oriented mounted rails. Mounting clamps and rail/clamp spacing configured to relieve module stress by reducing or eliminating module sag are used.

### FIELD OF THE INVENTION

This application relates generally to photovoltaic module installations and specifically to module mounting mechanisms for photovoltaic installations.

### BACKGROUND OF THE INVENTION

Photovoltaic cells are widely used for generation of electricity, with multiple photovoltaic cells interconnected in module assemblies. Such modules may in turn be arranged in arrays and integrated into building structures or otherwise assembled to convert solar energy into electricity by the photovoltaic effect. Arrays of modules are typically mounted on racking systems on the roof of buildings or on ground-based structures. The modules are required to pass load testing to ensure that they can safely withstand snow loading and other environmental conditions. This can be challenging for frameless photovoltaic modules.

SUMMARY OF SPECIFIC EMBODIMENTS

The invention relates generally to apparatus and techniques for mounting frameless photovoltaic modules to eliminate obstruction of corner and edge-mounted module components with longitudinally-oriented mounted modules. The invention further involves mounting clamps and rail/clamp spacing configured to relieve module stress by reducing or eliminating module sag.

In one aspect, the invention relates to a photovoltaic assembly. The photovoltaic assembly includes a frameless photovoltaic module comprising a frontside sheet and a backside sheet, a mounting structure comprising module mounting rails, and a plurality of standoff clamps mounted to at least two rails of the mounting structure and engaging the frontside sheet and the backside sheet of the frameless photovoltaic module at edge regions of the module, thereby securing the frameless photovoltaic module on the mounting structure, wherein the standoff clamps comprise a standoff portion.

Another aspect of the invention relates to a method of installing a frameless photovoltaic module comprising a frontside sheet and a backside sheet onto a mounting structure, the method comprising providing the mounting structure comprising module mounting rails, providing the frameless PV module, and securing the frameless photovoltaic module onto the mounting structure with a plurality of standoff clamps attached to at least two rails of the mounting structure and engaging the frontside of the frameless photovoltaic module at edge regions of the module overlying at least two rails, wherein the standoff clamps comprise a standoff portion.

These and other aspects of the invention are described further below with reference to the figures.

### BRIEF DESCRIPTION OF THE DRAWINGS

FIG. 1A shows a cross-sectional view of representative frameless photovoltaic module in accordance with the present invention.

FIG. 1B illustrates orientation conventions referenced in this document with respect to a representative frameless photovoltaic module in accordance with the present invention.

FIG. 2A depicts a partial plan view of an example frameless photovoltaic module mounting rail installation on a household roof.

FIG. 2B depicts a partial plan view of an example frameless photovoltaic module mounting rail installation on a household roof with frameless photovoltaic modules installed.

FIG. 2C shows a side view of an example frameless photovoltaic module mounting rail installation on a household roof with frameless photovoltaic modules installed.

FIG. 3A shows a perspective view of a household roof with an outline of underlying roof rafters.

FIG. 3B shows a top partial plan view of a household roof with an outline of underlying roof rafters.

FIG. 4A shows a side view of an example frameless photovoltaic module with corner-mounted components attached to conventional rail clamps disposed above a mounting rail.

FIG. 4B shows a side view of an example frameless photovoltaic module mounting rail installation comprising a frameless photovoltaic module with corner-mounted components installed using standoff clamps.

FIG. 4C shows a perspective plan view of an example frameless photovoltaic module mounting rail installation comprising a frameless photovoltaic module with corner-mounted components installed using standoff clamps.

FIG. 5A is a perspective view of a representative standoff clamp.

FIG. 5B is a perspective view of an alternative embodiment of a standoff clamp.

FIG. 5C is a perspective view of an alternative embodiment of a standoff clamp.

FIG. 6A is a plot of an analysis of the stress in a representative frameless photovoltaic module when installed with carious mounting clamp positions.

FIG. 6B is a stress contour plot of a representative frameless photovoltaic module and clamping system.

FIG. 7 is a flow diagram for a frameless photovoltaic module installation process in accordance with an embodiment of the invention utilizing the methods and equipment discussed in this application.

### DETAILED DESCRIPTION OF PREFERRED EMBODIMENTS

Reference will now be made in detail to specific embodiments of the invention. Examples of the specific embodiments are illustrated in the accompanying drawings. While the invention will be described in conjunction with these specific embodiments, it will be understood that it is not intended to limit the invention to such specific embodiments. On the contrary, it is intended to cover alternatives, modifications, and equivalents as may be included within the spirit and scope of the invention. In the following description, numerous specific details are set forth in order to provide a thorough understanding of the present invention. The present invention may be practiced without some or all of these specific details. In other instances, well known mechanical apparatuses and/or process operations have not been described in order not to unnecessarily obscure the present invention.

### Frameless Photovoltaic Modules

Photovoltaic modules often comprise corner or edge-mounted components that can present mounting challenges when implemented with certain mounting systems and components. Furthermore, photovoltaic modules are required to meet load ratings specified by IEC 61646 and UL 1703, incorporated herein by reference for this purpose. In this regard, a module must be able to pass a 2400 MPa static load test for wind and 5400 MPa static loading test for snow/ice. This load testing requirement can be particularly challenging for a frameless photovoltaic module (a module without a metallic frame around its perimeter) to meet. Further, the structural stability and module integrity can be difficult to preserve in a racking system for frameless photovoltaic modules.

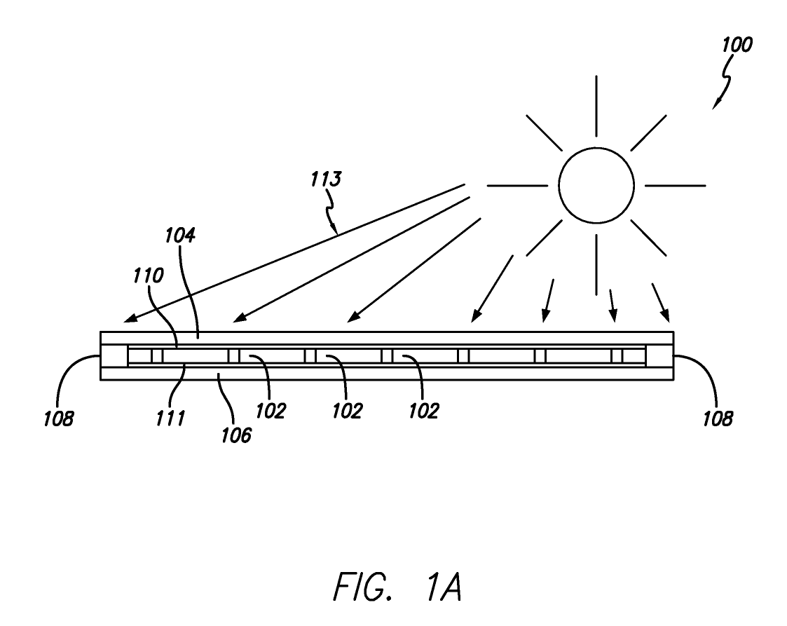

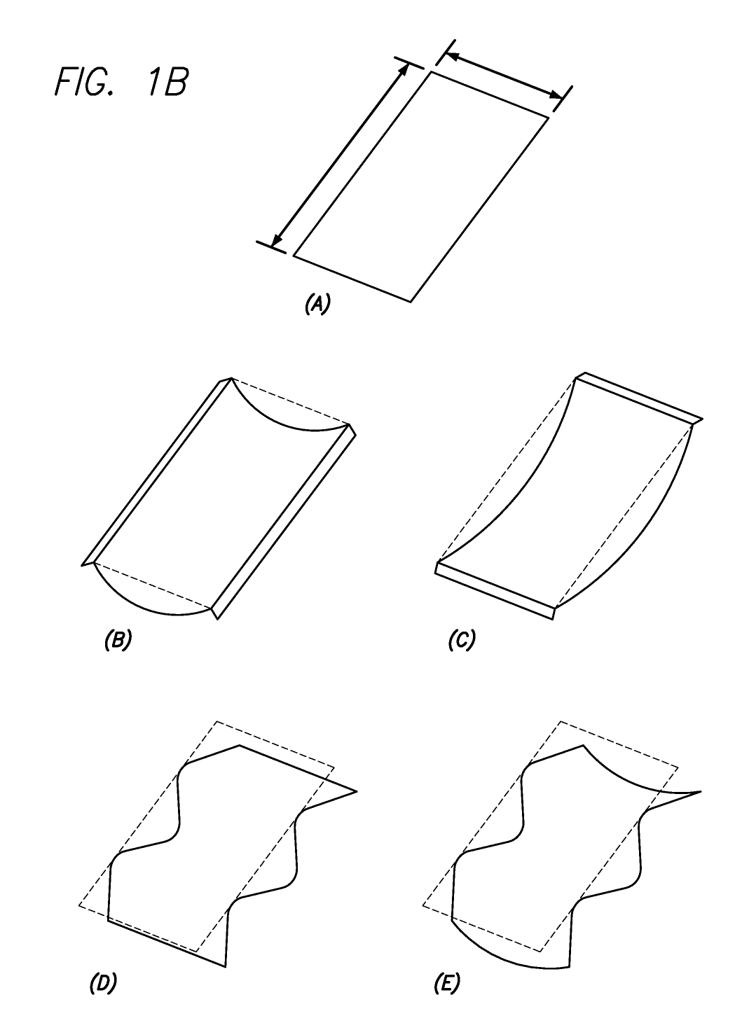

Embodiments of the present invention relate to mounting of frameless photovoltaic modules (also referred to as solar modules or solar panels or, in this application, simply as modules), and associated racking systems and methods. FIG. 1A shows a not-to-scale cross-sectional view of certain components of a frameless solar module 100 in accordance with one embodiment of the present invention. The module 100 includes interconnected solar cells 102 and front (light-incident) and back layers 104 and 106, respectively, for environmental protection and mechanical support. A light-transmissive thermoplastic polymer encapsulant 110 is also provided between the solar cells 102 and the front layer 104 to provide electrical insulation and further protection to the underlying solar cells by preventing direct contact between the solar cells and the generally rigid front layer 104. The same or a different encapsulant layer 111 may also be provided between the solar cells 102 and the back layer 106 for the same reasons. In certain modules, an additional edge material 108 surrounds the solar cells 102, and in this example, is embedded within encapsulating layers 110 and 111.

The front and back layers may be any suitable material that provides the environmental protection and mechanical support required for reliable module operation. In some typical embodiments, the front and back layers are rigid plates, light transmitting in the case of the front layer, such as glass, although other materials, such as polymers, multi-layer laminates and metals that meet the functional requirements may also be used. In other embodiments the typical rigid back layer (e.g., back glass plate) can be replaced with a much lighter weight flexible material, thereby reducing handling costs associated with the module.

The front, light-incident layer 104 should transmit visible and near visible wavelengths of the solar spectrum 113 and be chemically and physically stable to anticipated environmental conditions, including solar radiation, temperature extremes, rain, snow, hail, dust, dirt and wind to provide protection for the module contents below. A glass plate comprising any suitable glass, including conventional and float glass, tempered or annealed glass, combinations thereof, or other glasses, is preferred in many embodiments. The total thickness of a suitable glass or multi-layer glass layer 104 may be in the range of about 2 mm to about 15 mm, optionally from about 2.5 mm to about 10 mm, for example about 3 mm or 4 mm. As noted above, it should be understood that in some embodiments, the front layer 104 may be made of a non-glass material that has the appropriate light transmission, stability and protective functional requirements. The front layer 104, whether glass or non-glass, transmits light in a spectral range from about 400 nm to about 1100 nm. The front layer 104 may not necessarily, and very often will not, transmit all incident light or all incident wavelengths in that spectral range equally. For example, a suitable front layer is a glass plate having greater than 50% transmission, or even greater than 80% or 90% transmission from about 400-1100 nm. In some embodiments, the front layer 104 may have surface treatments such as but not limited to filters, anti-reflective layers, surface roughness, protective layers, moisture barriers, or the like. Although not so limited, in particular embodiments the front layer 104 is a tempered glass plate about 3 mm thick.

The back layer 106 may be the same as or different than the front layer 104 and is also typically a glass plate as described above. However, since the back layer 106 does not have the same optical constraints as the front layer 104, it may also be composed of materials that are not optimized for light transmission, for example metals and/or polymers. And, while the present invention is applicable in more typical module configurations having both front and back glass plate layers, the invention finds particularly advantageous application in embodiments in which the back layer 104 is a lighter weight flexible material. Such lighter weight modules have manufacturing and transportation benefits, but can present additional challenges for module stability, including compliance with load testing requirements stresses induced by module mounting configurations. In such embodiments, the back layer 106 may be a flexible yet weatherable laminate that protects the photovoltaic cells and other module components from moisture, UV exposure, extreme temperatures, etc. The back layer laminate may include a weatherable back sheet exposed to the exterior of the module. The back sheet should be resistant to environmental conditions expected to be experienced by the module (e.g., temperatures of about −40 to 90° C.), so that it is stable throughout the range of temperate climate temperatures and conditions so as to retain its properties to perform its protective function.

The back sheet may be composed of a fluoropolymer, including but not limited to polyvinyl fluoride (PVF) (e.g., Tedlar® film available from DuPont), polyvinylidene fluoride (PVDF), ethylene-tetrafluoroethylene (ETFE), fluorinated ethylene-propylene (FEP), perfluoroalkoxy (PFA) and polychlorotrifluoroethane (PCTFE). Other weatherable materials may be used in addition to or instead of a fluoropolymer, including silicone polyesters, chlorine-containing materials such as polyvinyl chloride (PVC), plastisols, polyethylene terephthalate (PET), polypropylene, polybutylene, polybutylene terephthalate, and acrylics or combinations (laminated stacks) of the above. In certain embodiments, any material that meets UL 1703 requirements (incorporated by reference herein) can be used. In one example, the back layer includes PVF (e.g., Tedlar®). In certain examples, the thickness may range from about 2 to about 12 mils, although other thicknesses may be used as appropriate. A suitable flexible back layer laminate may also include a flexible moisture barrier sandwiched between an insulation sheet, for example a sheet of PET, and the weatherable back sheet. A suitable moisture barrier may be a metallic sheet, such as an aluminum foil. A suitable laminate back sheet in accordance with some embodiments of the invention is composed of a polyvinyl fluoride/Al foil/polyethylene terephthalate laminate (e.g., Tedlar®/Al foil/PET). Further description of suitable flexible back layers for photovoltaic cells that may be used in modules in accordance with the present invention is provided in U.S. Published Patent Application No. 2008/0289682 and U.S. Published Patent Application No. 2010-0071756, each of which is incorporated by reference herein for this purpose.

The edge material 108 may be an organic or inorganic material that has a low inherent water vapor transmission rate (WVTR) (typically less than 1-2 g/m²/day) and, in certain embodiments may absorb moisture and/or prevent its incursion. In one example, a butyl-rubber containing a moisture getter or desiccant is used.

The solar cells 102 may be any type of photovoltaic cell including crystalline and thin film cells such as, but not limited to, semiconductor-based solar cells including microcrystalline or amorphous silicon, cadmium telluride, copper indium gallium selenide or copper indium selenide, dye-sensitized solar cells, and organic polymer solar cells. In particular embodiments, the cells are copper indium gallium selenide (CIGS) cells. In other aspects of the invention, the cells can be deposited as thin films on the front, light-incident (e.g., glass) layer 104. Direct deposition of a solar cell on glass is described, for example, in U.S. Published Patent Application No. 2009/0272437, incorporated by reference herein for this purpose. In such an embodiment, element 110 of FIG. 1A would be absent and element 102 would be in contact with the front, light-incident layer 104.

Frameless photovoltaic modules are often rectangular in overall shape, as shown in FIG. 1B. For purposes of discussion, references to frameless photovoltaic modules herein will be made in the context of a rectangular module possessing a longitudinal axis or direction and a transverse axis or direction (as depicted in FIG. 1B, diagram (a)), wherein the longitudinal axis is along the major (larger) dimension of the rectangle and the transverse axis is along the minor (smaller) dimension of the rectangle. Similarly, reference may be made to the length and width of the module. The length of a module refers to the major dimension of the rectangle; the width of a module refers to the minor dimension of the rectangle. Of course, frameless photovoltaic modules may take on a variety of forms departing from a rectangle, and reference to rectangular modules, rectangles, and longitudinal or transverse axes, dimensions, or directions, should not be viewed as limiting the invention only to rectangular modules.

Reference is also made in this application to sagging of a frameless photovoltaic module. In some cases, a module will be described as experiencing sagging along a transverse or longitudinal direction. Sag along a transverse direction refers to sagging behavior which manifests as a non-linear displacement of the module from a line running in a transverse direction, as depicted in FIG. 1A, diagram (b). Sag along a longitudinal direction refers to sagging behavior which manifests as a non-linear displacement of the module from a line running in a longitudinal direction, as depicted in FIG. 1A, diagram (c). A module may sag at multiple points depending on the method of support, as depicted in FIG. 1B, diagram (d). Sag may occur along both transverse and longitudinal directions to different degrees at the same time and result in complex overall displacement, as depicted in FIG. 1B, diagram (e).

### Frameless Photovoltaic Module Mounting Rail Systems

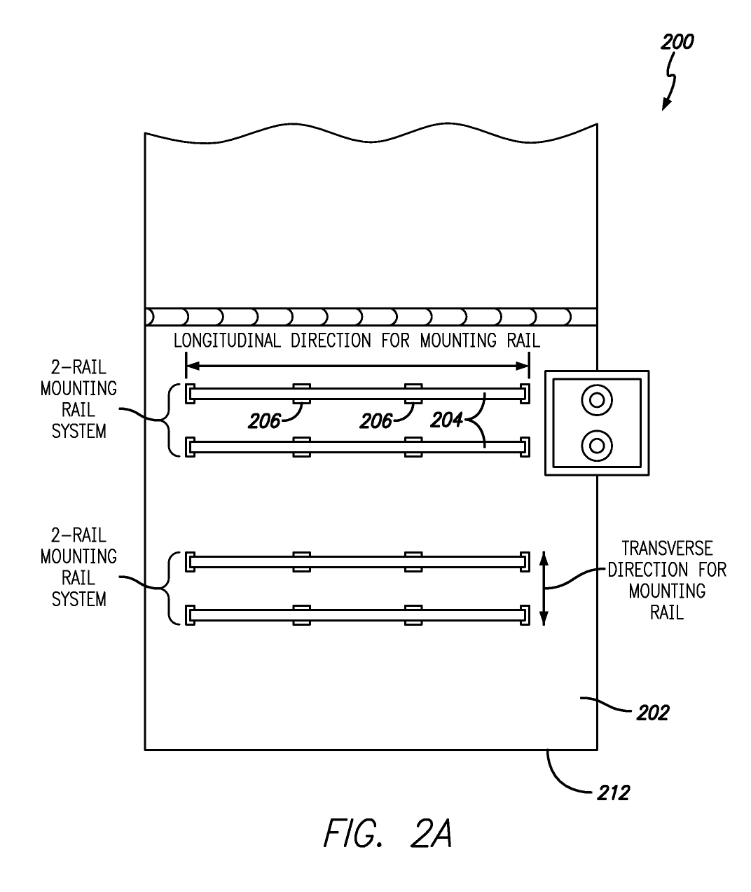

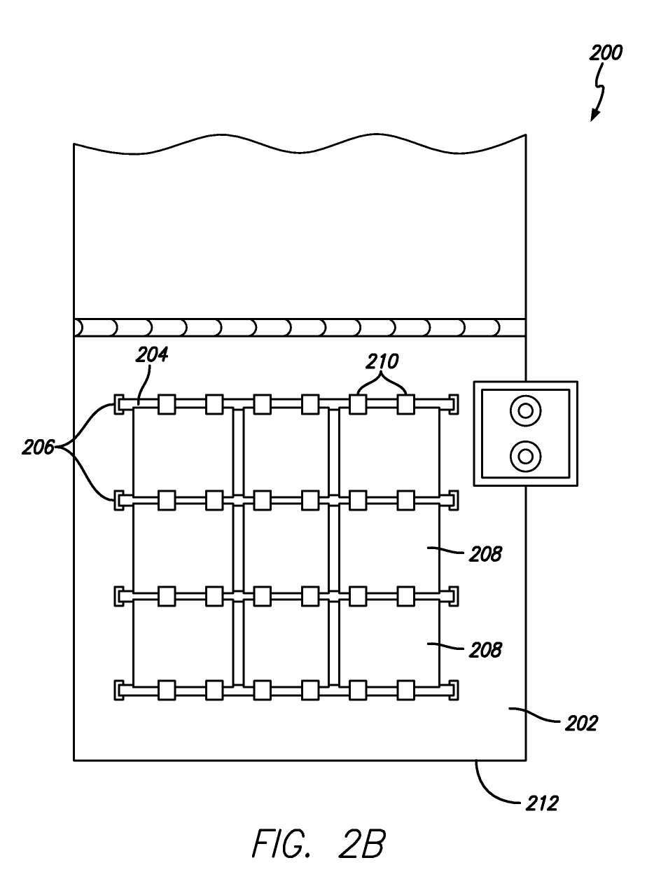

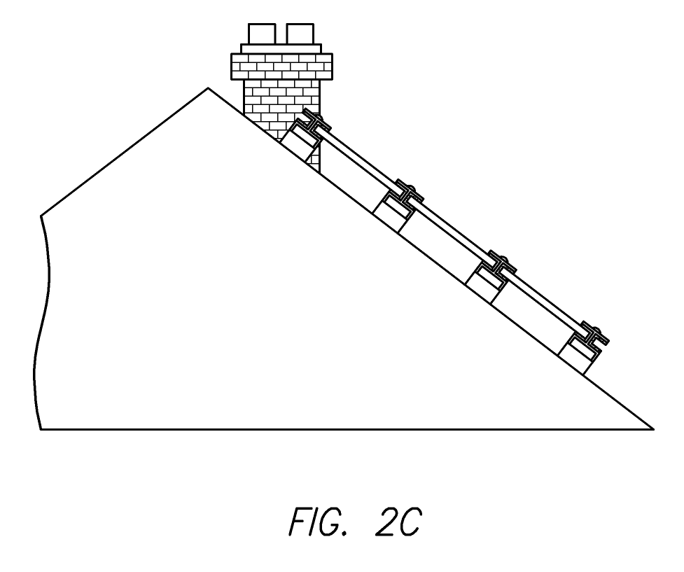

Frameless photovoltaic modules are often mounted onto racking or mounting rail systems when installed at their installation locations. A plan view of an example mounting rail system is shown in FIGS. 2A and 2B. Such mounting rail systems 200 are frequently attached to freestanding support structures, roofs 202, carports, walls, or other structures which receive exposure to sunlight and can support the weight of the mounting rails 204 and installed frameless photovoltaic modules 208. All such structures are often oriented, or may be re-oriented, to present the mounted frameless photovoltaic modules 208 in an orientation that promotes efficient solar power generation.

In one embodiment, the mounting rail system includes two or more rails 204 which support one or more frameless photovoltaic modules 208. The mounting rails 204 may be substantially longer than the mounting rails 204 are wide or deep. For example, a mounting rail 204 may have overall dimensions of 1″ wide by 3″ deep, but be 144″ long. Several sections of mounting rail 204 may also be connected end-to-end or be butted up to one another to form a much longer mounting rail. The mounting rails 204 may be mounted to a structure, such as roof 202, either directly or using standoffs 206. The mounting rails 204 may also be attached to a supplemental support structure; the supplemental support structure may elevate the rails or position the mounting rails 204 in a more optimum manner (e.g., position the mounting rails 204 such that attached frameless photovoltaic modules 208 will be oriented towards the sun to a greater extent).

The mounting rails 204 may be manufactured from extruded or rolled materials, such as aluminum or steel, or from other materials or using other manufacturing techniques. The mounting rails 204 may be hollow, solid, or filled with material, such as foam or honeycombs. The mounting rails 204 may include grooves, holes, t-slots, or other features which allow for hardware to be attached to the mounting rails 204; these features may provide pre-set hardware position points (e.g., pre-drilled holes) or allow for infinite positioning of hardware locations (e.g., grooves or t-slots).

For purposes of discussion, reference to the longitudinal direction or axis of a mounting rail refers to the direction or axis aligned with the substantially longer dimension of the mounting rail. As illustrated in FIG. 2A, reference to the transverse direction or axis of a mounting rail refers to the direction or axis of the mounting rail perpendicular to the longitudinal direction of axis of the mounting rail.

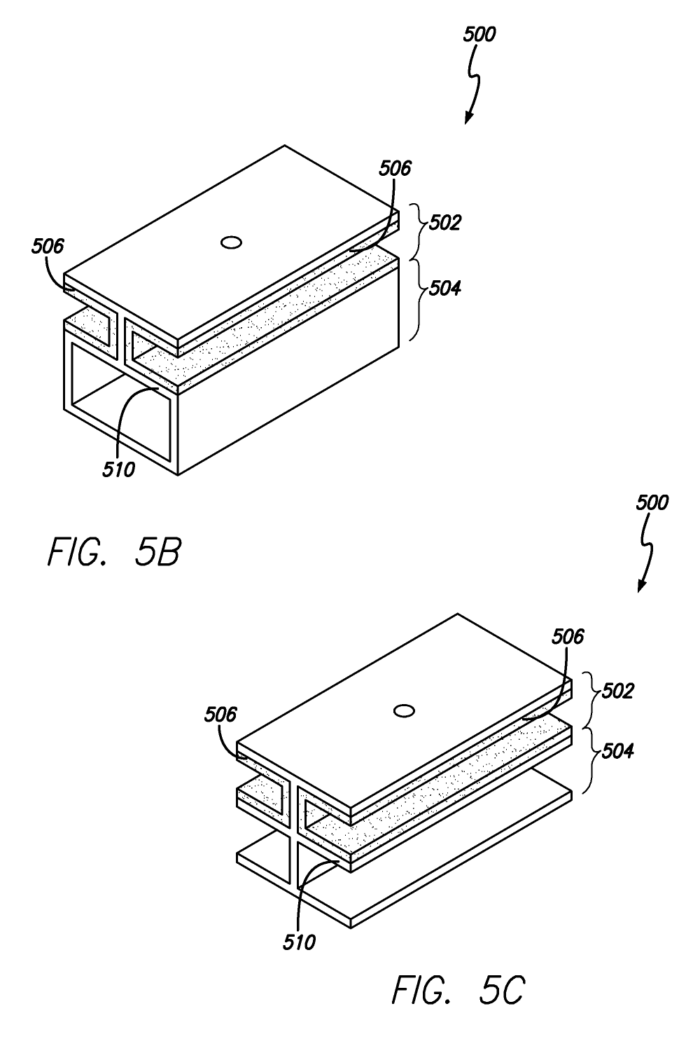

Frameless photovoltaic modules may be mounted to mounting rails 204 using one or more standoff clamps 210. Representative standoff clamps are discussed in greater detail below with reference to FIGS. 5A-5C.

Frameless photovoltaic modules mounted to rail mounting systems may experience sagging in areas not directly supported by a standoff clamp due to the modules' weight and geometry. In a two-rail mounting system, a frameless photovoltaic module will typically only be externally supported at the standoff clamp locations. In areas where the frameless photovoltaic module does not receive external support, the module must be self-supporting, i.e., the module must rely on the material properties and geometry of the module for support.

The standoff clamps may be spaced according to the L/4 rule, in which the midpoints standoff clamps are typically positioned at a distance of L/4 from the transverse edges of a module, where L refers to the length of the module. For example, for a 1611 mm×665 mm module, the L/4 distance would be 402.75 mm.

In one embodiment, the transverse midpoint of each standoff clamp in a two-row standoff clamp configuration is instead positioned approximately 22% of the length of the module from the transverse edges of the module. Thus, for a 1611 mm×665 mm module, the midpoints of the standoff clamps would be positioned about 354.4 mm from either transverse edge along the longitudinal axis.

More particularly, the midpoint of each standoff clamp in a two-row standoff clamp configuration may be positioned approximately 22.3% of the length of the module from a transverse edge of the module. 55.4% of the module would thus be located between the midpoints of the two rows of standoff clamps.

### Clamping Systems

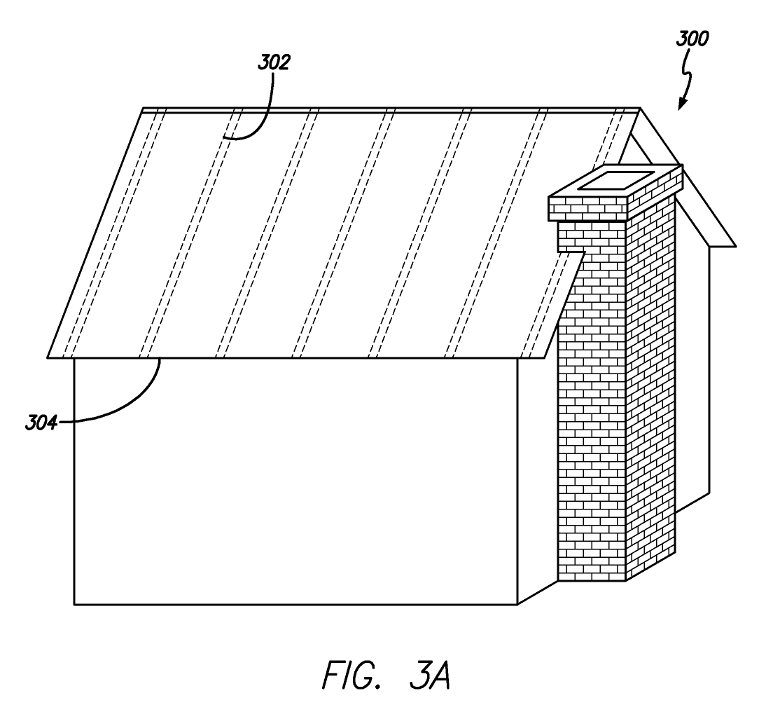

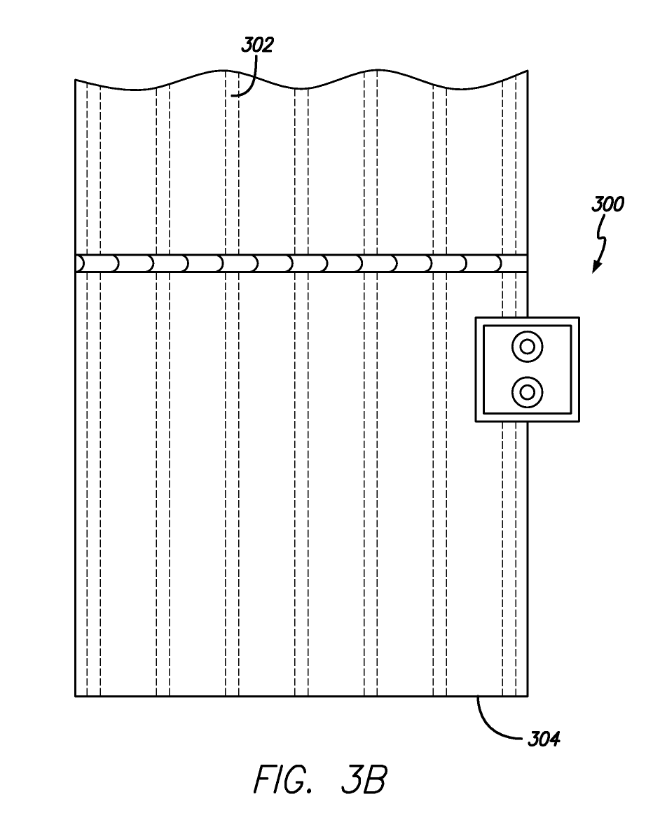

The orientation of the mounting rail system shown in FIGS. 2A and 2B wherein the longitudinal direction for the mounting rail runs parallel to the lower eave 212 of the roof is particularly advantageous in sloped roofing. For the purposes of this disclosure, this orientation will be referred to as a “longitudinally-eave-parallel” mounting rail system. This orientation is particularly advantageous in sloped roofs 300, like that shown in FIGS. 3A and 3B, because the rafters 302 of the roof generally run perpendicular to the bottom eave 304 of the roof. Mounting rails are commonly affixed to the rafter of the underlying structure using mechanisms such as L-clamps. The mounting rails of a longitudinally-eave-parallel mounting rail system, wherein the mounting rails are oriented perpendicular to the underlying rafters, may be affixed to the underlying rafters at any point where the rails cross the underlying rafters. This is preferred to mounting systems wherein the mounting rails run parallel to the underlying rafters which make it difficult to affix the rails to the underlying rafter unless the rails are disposed directly over the rafters or if intermediate cross-rails are installed perpendicular to the rafters. Having to place the mounting rails parallel to and directly over the underlying rafters severely limits installation options and module dimensions while the addition of intermediate cross-rails significantly adds to the cost of the installation due to increase in cost of materials as well as labor.

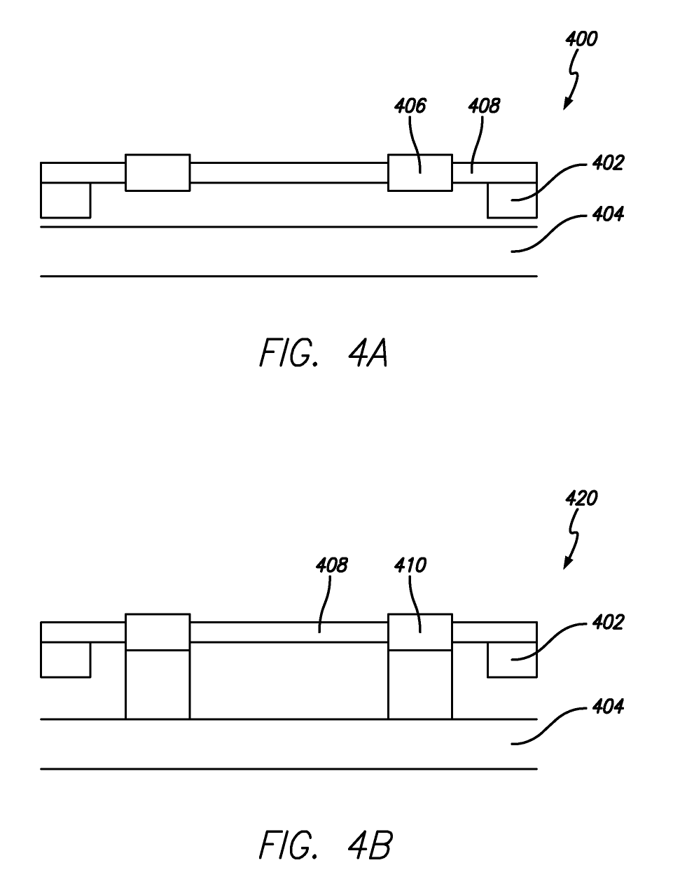

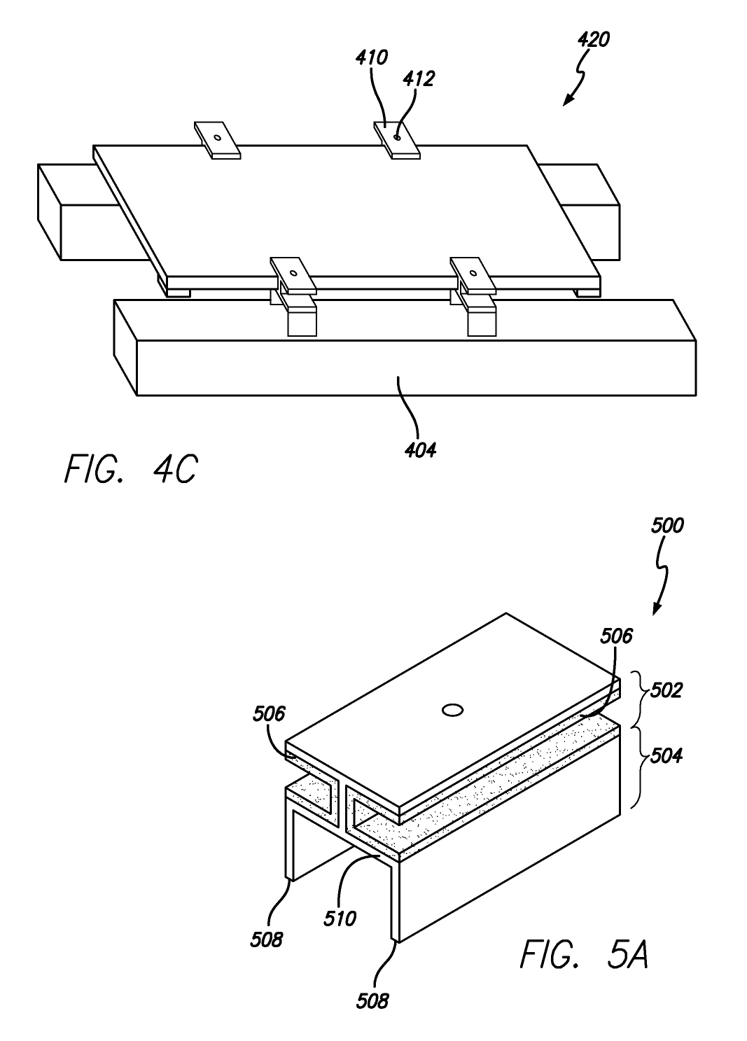

Many frameless photovoltaic modules comprise externally mounted components such as junction boxes, electronic equipment or other components mounted on corner or longitudinal edge regions of the modules. Such components may make it difficult to install the modules on longitudinally-eave-parallel mounting rail systems or ground-mounted mounting rails where the mounting rail runs directly under a module edge comprising an externally-mounted component, due to interference of the components with the mounting rails. FIG. 4A shows an example clamping arrangement 400 wherein the corner-mounted components 402 of the frameless module 408 interfere with the rails 404 of the rail system when conventional clamps 406 are used for installation.

In order to clamp the frameless modules to the rail mounting system, a standoff clamp may be used to create a gap between the frameless module 408 and the mounting rail 404 wherein the gap provides sufficient space so that the components 402 on the corners or the longitudinal edges of the modules do not interfere with the mounting rails. After installation using standoff clamps, the gap between the frameless module and the mounting rail may be 0.5 to 5.0 inches, such as 1.0 to 3.0 inches. FIGS. 4B-4C depict an example clamping arrangement 420. In this arrangement, a standoff clamp 410 is used to affix the frameless module 408 to the mounting rails 404 creating a gap between the frameless module 408 and the mounting rail 404 wherein the components 402 do not interfere with the mounting rail 404.

Examples of certain embodiments of standoff clamps are shown in FIGS. 5A-5C. The standoff clamp may comprise multiple pieces and may include a rigid mounting bracket 510 and an elastomeric cushion 506. The rigid mounting bracket may, for example, be made from plastic or metal, such as aluminum and may comprise a clamp portion 502 and a standoff portion 504. The clamp portion refers to the portion(s) of the bracket 510 which engages the frontside surface and the backside surface of at least one frameless module and the standoff portion refers to the portion which supports the clamps and engages the mounting rails. The clamp portion may be configured to engage one or more photovoltaic modules. For example, the embodiments shown in FIGS. 5A-5C comprise clamp portions 502 that are configured to engage two modules. However, it should be recognized that standoff clamps could be configured to engage one module or more than two modules and that such embodiments are within the scope of the present invention. The clamp portion 502 may comprise an elastomeric cushion(s) 506 which may be configured to engage a photovoltaic module along the frontside surface, a backside surface, and along an edge surface. Alternatively, elastomeric cushion(s) 506 may be configured to only engage a frameless module along the frontside surface and the backside surface. Elastomeric cushion(s) 506 and rigid mounting bracket 510 may include matching boss/relief features which may facilitate maintaining positional alignment between elastomeric cushion(s) 506 and rigid mounting bracket 510. Elastomeric cushion(s) may have a thickness of about 3 mm. Elastomeric cushion 506 may, for example, be made from an elastomer such as ethylene propylene diene monomer (EPDM) rubber, butyl rubber, or silicone rubber. For example, EPDM rubber having a Shore hardness of 60A may be used. The standoff portion may further comprise a rail engagement portion 512 which is the portion of the clamp that contacts the mounting rail. The rail engagement portion 512 may have a solid base configuration such as that shown in FIGS. 5B and 5C. Alternatively, the standoff portion may comprise a forked rail engagement portion 508 such as that shown in FIG. 5A. The standoff clamp may be attached to the mounting rail 404 using mounting bolt 412.

### Example Modeling

Modeling was conducted in order to demonstrate the advantages provided by various aspects of this invention with regard to the positioning of the standoff clamps along the longitudinal edge of the module. The data presented here are intended to better illustrate the invention as described herein and are non-limiting.

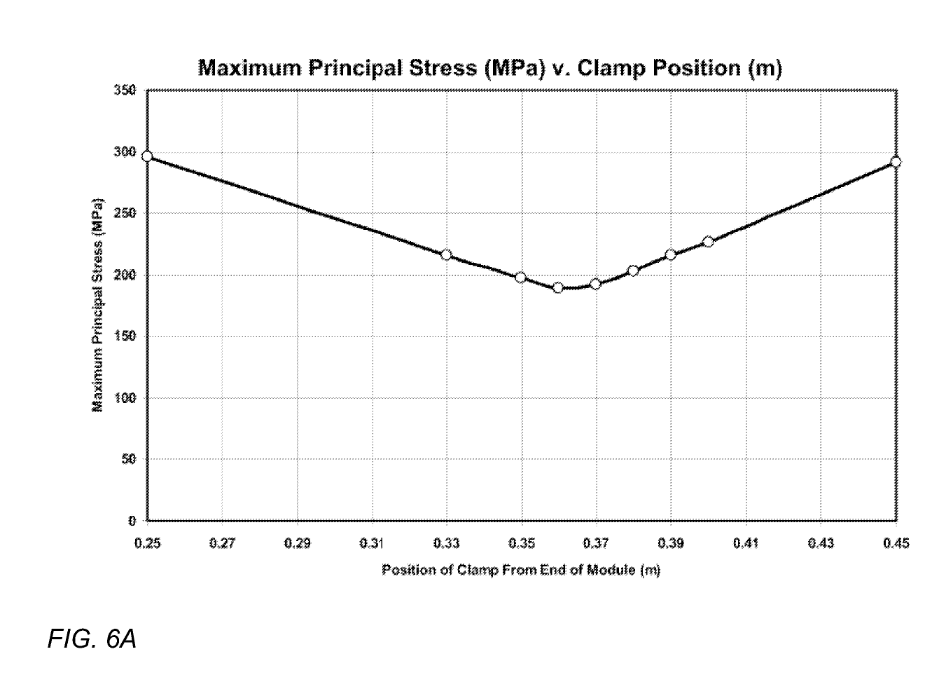

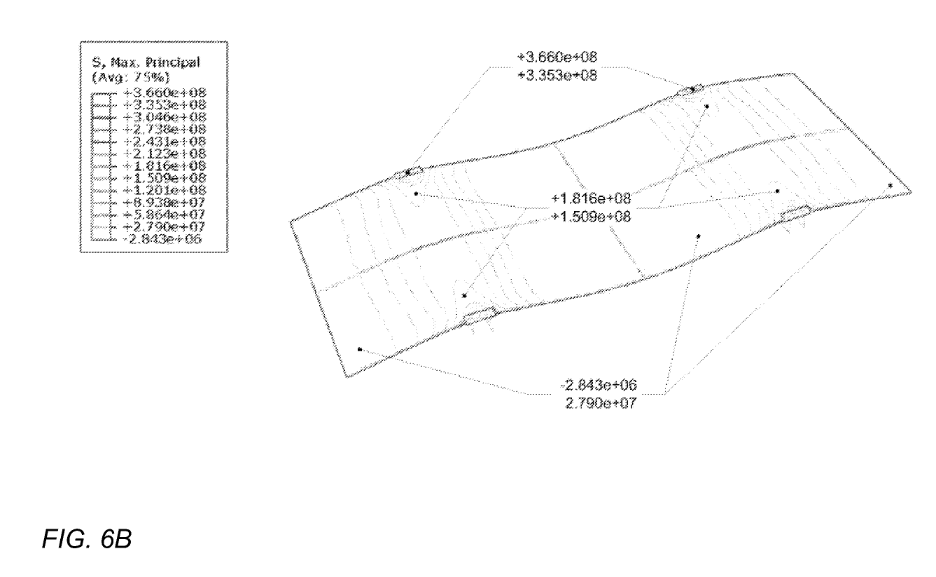

FIG. 6A depicts a plot of the maximum principal stress experienced by a typical module depending on the distance the clamps are from the transverse edge of the module. For the analyzed module, positioning standoff clamps at approximately 22% of the longitudinal length of the module from either transverse edge reduced the resulting maximum principal stress by approximately 37 MPa relative to the stress induced by a L/4 clamp spacing.

FIG. 6B is a stress contour plot of an example frameless photovoltaic module supported by four standoff clamps. The clamp spacing in this plot is approximately 22% of the module longitudinal length from either transverse edge. The combination of sag loading and localized stress concentrations in the regions of the edge clamps results in a peak principal stress of 366 MPa.

### Example Installation Process

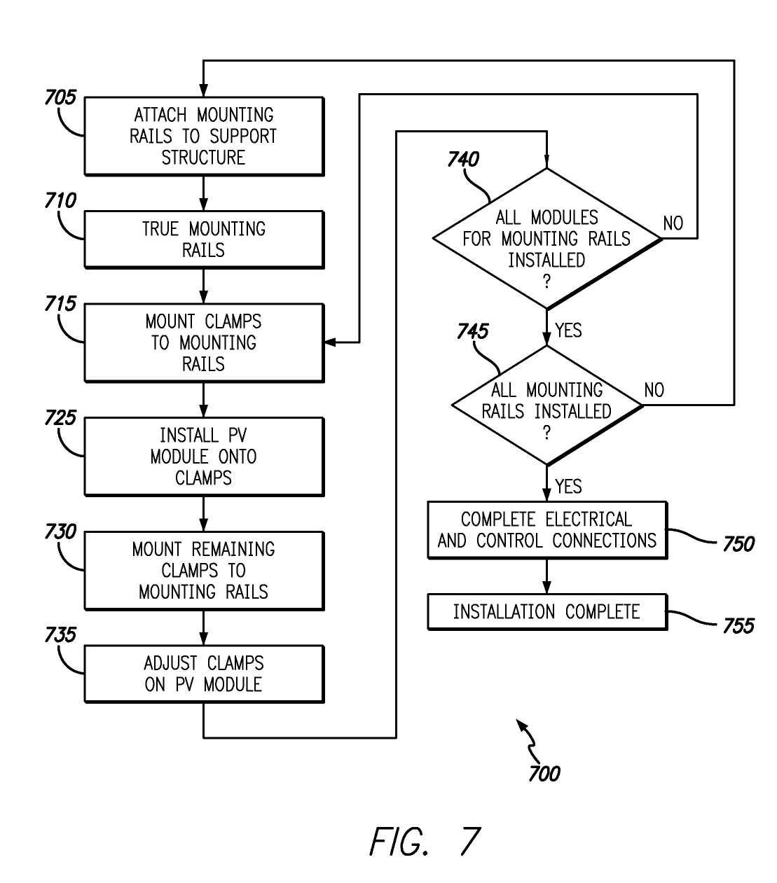

An example installation process utilizing mounting rail systems in conjunction with standoff clamps is diagrammed in FIG. 7. it should be noted that not all of the operations depicted and described are necessarily part of a process in accordance with the present invention; an installation process in accordance with the invention may include all or just some of the operations described. A number of the operations are provided for context to facilitate description and understanding of the invention, but are optional in some embodiments.

Installation process 700 begins with the installation of mounting rails onto a support structure. This may include attaching one or more mounting rails to a roof, carport, or other support structure. Standoffs and mounting hardware may be used to implement the attachment. In the case of a pre-existing mounting rail installation, such as in a retrofit, reinstallation of the mounting rails may not be necessary.

In step 710, the mounting rails may be trued to remove any gross variation in mounting rail parallelity and levelness.

In step 715, module clamping hardware is mounted to the installed mounting rails. Of course, the clamping hardware may also be installed prior to truing 710 or prior to rail installation 705. In some cases, only the clamps which will engage one longitudinal side of a module will initially be installed. In other cases, all clamps for a module will be installed. The clamps may be securely attached to the mounting rails.

In step 725, a module is installed into the mounted clamps. Installing a module may involve sliding the module in a transverse direction into the gap between the clamp finger and the mounting rail. Alternatively, the module may be installed onto the mounting rails and any mounted clamps may then be slid into position to engage the frontside of the module.

In step 730, any remaining clamps, or clamp components, required to secure the module are installed.

In step 735, the clamps are adjusted to ensure uniformity in clamping force and position.

In step 540, the installation process returns to step 715 if any modules remain which will be installed on the installed mounting rails.

In step 545, the installation process returns to step 705 if there are any mounting rails remaining to be installed.

In step 550, electrical and control connections are made to the mounted modules, and any support electronics are installed and configured. In step 755, the mechanical installation is complete.

Of course, the above steps are merely examples of an installation process using the described technology. The ordering of the steps may be changed significantly—for example, it is not necessary to install the modules for one set of rails before installing a second set of rails. The order set forth in FIG. 7 should not be construed as limiting in any way.

### CONCLUSION

Although the foregoing invention has been described in some detail for purposes of clarity of understanding, it will be apparent that certain changes and modification may be practiced within the scope of the invention. It should be noted that there are many alternative ways of implementing both the processes and apparatuses of the present invention. Accordingly, the present embodiments are to be considered as illustrative and not restrictive, and the invention is not to be limited to the details given herein.

What is claimed is:

1. A photovoltaic module assembly comprising:
a frameless photovoltaic module comprising a frontside sheet and a backside sheet;
a mounting structure comprising module mounting rails; and
a plurality of standoff clamps mounted to at least two rails of the mounting structure and engaging the frontside sheet and the backside sheet of the frameless photovoltaic module at edge regions of the module, thereby securing the frameless photovoltaic module on the mounting structure, wherein the standoff clamps comprise a standoff portion.

2. The photovoltaic module assembly of claim 1, wherein the plurality of standoff clamps are configured to secure the module to the mounting structure in a manner that creates a gap between the module and the mounting structure, wherein the gap is 0.5 to 5.0 inches.

3. The photovoltaic module assembly of claim 2, wherein the gap is 1.0 to 3.0 inches.

4. The photovoltaic module assembly of claim 1, wherein the plurality of standoff clamps secure the frameless module on the mounting structure across the longitudinal length of the module.

5. The photovoltaic module assembly of claim 1, wherein the each of the plurality of standoff clamps comprises a rigid portion and an elastomeric portion.

6. The photovoltaic module assembly of claim 5, wherein the elastomeric portion of each of the plurality of standoff clamps engages the frameless module.

7. The photovoltaic module assembly of claim 5, wherein the elastomeric portion of each of the plurality of standoff clamps is selected from a group consisting of EPDM rubber, butyl rubber and silicone rubber.

8. The photovoltaic module assembly of claim 7, wherein the elastomeric portion of each of the plurality of standoff clamps is EPDM rubber.

9. The photovoltaic module assembly of claim 8, wherein the EPDM rubber has a Shore hardness of about 60 A.

10. The photovoltaic module assembly of claim 1, wherein the plurality of standoff clamps are arranged in two rows, each row positioned about 22% of the module length from each end of the module.

11. The photovoltaic module assembly of claim 1, wherein the standoff portion comprises a base portion with a solid rail engagement portion.

12. The photovoltaic module assembly of claim 1, wherein the standoff portion comprises a base portion with a forked rail engagement portion.

13. The photovoltaic module assembly of claim 1, wherein the frontside sheet is a glass sheet.

14. The photovoltaic module assembly of claim 1, wherein the backside sheet is a glass sheet.

15. The photovoltaic module assembly of claim 1, wherein the backside sheet is a non-glass flexible sheet.

16. The photovoltaic module assembly of claim 15, wherein the backside sheet comprises one or more materials selected from the group consisting of a polyethylene terephthalate, a polypropylene, a polybutylene, and a polybutylene terephthalate.

17. The photovoltaic module assembly of claim 1, wherein the frameless photovoltaic module comprises a plurality of interconnected copper indium gallium selenide (CIGS) cells.

18. A method of installing a frameless photovoltaic module comprising a frontside sheet and a backside sheet onto a mounting structure, the method comprising:
providing the mounting structure comprising module mounting rails;
providing the frameless PV module; and
securing the frameless photovoltaic module onto the mounting structure with a plurality of standoff clamps attached to at least two rails of the mounting structure and engaging the frontside of the frameless photovoltaic module at edge regions of the module overlying at least two rails, wherein the standoff clamps comprise a standoff portion.

19. The method of claim 18, wherein the plurality of standoff clamps are configured to secure the module to the mounting structure in a manner that creates a gap between the module and the mounting structure, wherein the gap is 0.5 to 5.0-inches.

20. The method of claim 19, wherein the gap is 1.0 to 3.0 inches.

21. The method of claim 18, wherein the plurality of standoff clamps secure the frameless module on the mounting structure across the longitudinal length of the module.

22. The method of claim 18, wherein each of the plurality of standoff clamps comprises a rigid portion and an elastomeric portion.

23. The method of claim 22, wherein the elastomeric portion of each of the plurality of clamps engages the frameless module.

24. The method of claim 23, wherein the elastomeric portion of each of the plurality of standoff clamps is selected from a group consisting of EPDM rubber, butyl rubber and silicone rubber.

25. The method of claim 24, wherein the elastomeric portion of each of the plurality of standoff clamps is EPDM rubber.

26. The method of claim 25, wherein the EPDM rubber has a Shore hardness of about 60 A.

27. The method of claim 18, wherein the plurality of standoff clamps are arranged in two rows, each row positioned about 22% of the module length from each end of the module.

28. The method of claim 18, wherein the standoff portion comprises a base portion with a solid rail-engagement portion.

29. The method of claim 18, wherein the standoff portion comprises a base portion with a forked rail-engagement portion.

30. The method of claim 18, wherein the frontside sheet is a glass sheet.

31. The method of claim 18, wherein the backside sheet is a glass sheet.

32. The method of claim 18, wherein the backside sheet is a non-glass flexible sheet.

33. The method of claim 32, wherein the backside sheet comprises one or more materials selected from the group consisting of a polyethylene terephthalate, a polypropylene, a polybutylene, and a polybutylene terephthalate.

34. The method of claim 18, wherein the frameless photovoltaic module comprises a plurality of interconnected copper indium gallium selenide (CIGS) cells.
